(19) United States
(12) Patent Application Publication
(10) Pub. No.: US 2026/0068282 A1
(43) Pub. Date: Mar. 5, 2026

(54) SEMICONDUCTOR DEVICES INCLUDING MULTILAYER INSULATION STRUCTURE

(71) Applicant: Samsung Electronics Co., Ltd., Suwon-si (KR)

(72) Inventors: So Young Lee, Suwon-si (KR); Kwan Soo Kim, Suwon-si (KR); Ju Youn Kim, Suwon-si (KR); Jung-Min Park, Suwon-si (KR); Chang Gi Cho, Suwon-si (KR)

(21) Appl. No.: 19/056,161

(22) Filed: Feb. 18, 2025

(30) Foreign Application Priority Data
Aug. 28, 2024 (KR) 10-2024-0116196

(51) Int. Cl. H10D 64/68; H10D 30/00

(52) U.S. Cl. CPC H10D 64/685; H10D 30/501; H10D 64/691

(57) ABSTRACT

Provided is a semiconductor device including a substrate, a first active pattern on the substrate, including a first lower pattern and a plurality of first sheet patterns spaced apart from the first lower pattern, a gate electrode on the substrate, and on the plurality of first sheet patterns, an interfacial layer between the plurality of first sheet patterns and the gate electrode and along the outer edge of each of the plurality of first sheet patterns, and a first insulating layer structure between the interfacial layer and the gate electrode and, wherein the first insulating layer structure includes a first insulating layer along on the interfacial layer, a first insertion insulating layer along on the first insulating layer, and a second insulating layer along on the first insertion insulating layer.

### CROSS-REFERENCE TO RELATED APPLICATION

This application claims priority from Korean Patent Application No. 10-2024-0116196 filed on Aug. 28, 2024 in the Korean Intellectual Property Office and all the benefits accruing therefrom under 35 U.S.C. 119, the contents of which in its entirety are herein incorporated by reference.

### TECHNICAL FIELD

The present disclosure relates to semiconductor devices.

### BACKGROUND OF THE INVENTION

As scaling techniques for increasing a density of a semiconductor device are improved, a multi-gate transistor for forming a multi-channel active pattern (or silicon body) of a fin or nanowire shape on a substrate and forming a gate on a surface of the multi-channel active pattern has been suggested.

Since this multi-gate transistor uses a three-dimensional channel, it is easy to scale the multi-gate transistor. Also, even though a gate length of the multi-gate transistor is not increased, a current control capability may be improved. In addition, a short channel effect (SCE) in which a potential of a channel region is affected by a drain voltage may be suppressed effectively.

As a pitch size of the semiconductor device is reduced, studies for reducing capacitance and ensuring heat discharge and electrical stability between contacts in the semiconductor device may be required.

### SUMMARY OF THE INVENTION

An object of the present disclosure is to provide a semiconductor device in which performance and reliability are improved.

According to some embodiments of the present disclosure, there is provided a semiconductor device comprising a substrate, a first active pattern on the substrate, including a first lower pattern and a plurality of first sheet patterns spaced apart from the first lower pattern in a first direction, a gate electrode on the substrate, and on the plurality of first sheet patterns, an interfacial layer between the plurality of first sheet patterns and the gate electrode and along an outer edge of each of the plurality of first sheet patterns, and a first insulating layer structure between the interfacial layer and the gate electrode and extending along the outer edge of each of the plurality of first sheet patterns, wherein the first insulating layer structure includes a first insulating layer along on the interfacial layer, a first insertion insulating layer along on the first insulating layer, and a second insulating layer along on the first insertion insulating layer.

According to some embodiments of the present disclosure, there is provided a semiconductor device comprising a substrate, a first active pattern on the substrate, including a first lower pattern and a plurality of first sheet patterns spaced apart from the first lower pattern in a first direction, a second active pattern on the substrate and spaced apart from the first active pattern in a second direction perpendicular to the first direction, including a second lower pattern and a plurality of second sheet patterns spaced apart from the second lower pattern in the first direction, a gate electrode on the substrate, and on the plurality of first sheet patterns and the plurality of second sheet patterns, a first insulating layer structure between the plurality of first sheet patterns and the gate electrode and along an outer edge of each of the plurality of first sheet patterns, and a second insulating layer structure between each of the plurality of second sheet patterns and the gate electrode and along an outer edge of each of the plurality of second sheet patterns, wherein the first insulating layer structure includes a first insulating layer along on each of the plurality of first sheet patterns, and a second insulating layer on the first insulating layer, wherein the second insulating structure comprises a third insulating layer along outer edges of each of the plurality of second sheet patterns, and a fourth insulating layer along outer edges of the third insulating layer, and wherein the first insulating layer structure includes a first insertion insulating layer between each pair of first and second insulating layers, but the second insulating layer structure does not include the first insertion insulating layer.

According to some embodiments of the present disclosure, there is provided a semiconductor device comprising a substrate, a first active pattern on the substrate, including a first lower pattern and a plurality of first sheet patterns spaced apart from the first lower pattern in a first direction, a second active pattern on the substrate and spaced apart from the first active pattern in a second direction perpendicular to the first direction, including a second lower pattern and a plurality of second sheet patterns spaced apart from the second lower pattern in the first direction, a gate electrode on the substrate, and on the plurality of first sheet patterns and the plurality of second sheet patterns, a first insulating layer structure between the plurality of first sheet patterns and the gate electrode and along on each of the plurality of first sheet patterns, and a second insulating layer structure between the plurality of second sheet patterns and the gate electrode and along on each of the plurality of second sheet patterns, wherein the first insulating layer includes a first insulating layer on the plurality of first sheet patterns, and a second insulating layer on the first insulating layer, wherein the second insulating layer structure includes a third insulating layer on each of the plurality of second sheet patterns, and a fourth insulating layer on the third insulating layer, and wherein the first insulating layer structure includes a first insertion insulating layer between each of the pair of first and second insulating layers, but the second insulating layer structure does not include the first insertion insulating layer.

However, embodiments of the present disclosure are not restricted to those set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

The above and other aspects and features of the present disclosure will become more apparent by describing in detail illustrative embodiments thereof with reference to the attached drawings.

FIG. 1 is an example plan view illustrating a semiconductor device according to some embodiments.

FIG. 2 is a cross-sectional view taken along line A-A′ of FIG. 1.

FIG. 3 is a cross-sectional view taken along line B-B′ of FIG. 1.

FIG. 4 is a cross-sectional view taken along line C-C′ of FIG. 1.

FIG. 5 is an enlarged view illustrating a portion P1 of FIG. 4.

FIG. 6 is an enlarged view illustrating a portion Q1 of FIG. 4.

FIGS. 7 and 8 are views illustrating a semiconductor device according to some embodiments of the present disclosure.

FIGS. 9 to 13 are views illustrating a semiconductor device according to some embodiments of the present disclosure.

FIGS. 14 to 18 are views illustrating a semiconductor device according to some embodiments of the present disclosure.

FIG. 19 is a view illustrating a semiconductor device according to some embodiments of the present disclosure.

FIG. 20 is a view illustrating a semiconductor device according to some embodiments of the present disclosure.

FIGS. 21 to 27 are views illustrating intermediate steps to describe a method for fabricating a semiconductor device according to some embodiments.

### DETAILED DESCRIPTION

It will be understood that, although the terms “first”, “second”, etc. may be used herein to describe various elements or components, these elements or components should not be limited by these terms. These terms are only used to distinguish one element or component from another element or component. Therefore, a first element or component discussed below could be termed a second element or component without departing from the technical spirits of the present disclosure. Also, a lower element or component mentioned below may be an upper element or component within the technical spirits of the present disclosure.

The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Likewise, when components are “immediately” adjacent to one another, no intervening components may be present.

Components or layers described with reference to “overlap” in a particular direction may be at least partially obstructed by one another when viewed along a line extending in the particular direction or in a plane perpendicular to the particular direction. The term “surrounding” or “covering” or “filling” as may be used herein may not require completely surrounding or covering or filling the described elements or layers, but may, for example, refer to partially surrounding or covering or filling the described elements or layers, for example, with voids or other discontinuities throughout.

Hereinafter, the embodiments of the present disclosure will be described in detail with reference to the accompanying drawings. The same reference numerals will be used for the same elements in the drawings, and their redundant description will be omitted.

In the drawings related to a semiconductor device according to some embodiments, a transistor including a nanowire or a nanosheet, that is, a multi-bridge channel field effect transistor (MBCFET™) is shown by way of example, but the present disclosure is not limited thereto. The semiconductor device according to some embodiments may be applied to a fin-type transistor (FinFET) including a channel region of a fin-type pattern shape.

The semiconductor device according to some embodiments may include a tunneling transistor (tunneling FET), a three-dimensional (3D) transistor or a vertical transistor (Vertical FET). The semiconductor device according to some embodiments may include a planar transistor. In addition, the technical spirits of the present disclosure may be applied to two-dimensional (2D) material-based transistors (FETs) and a heterostructure thereof.

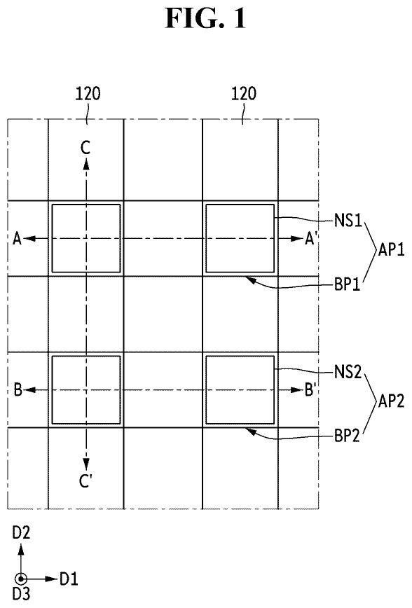

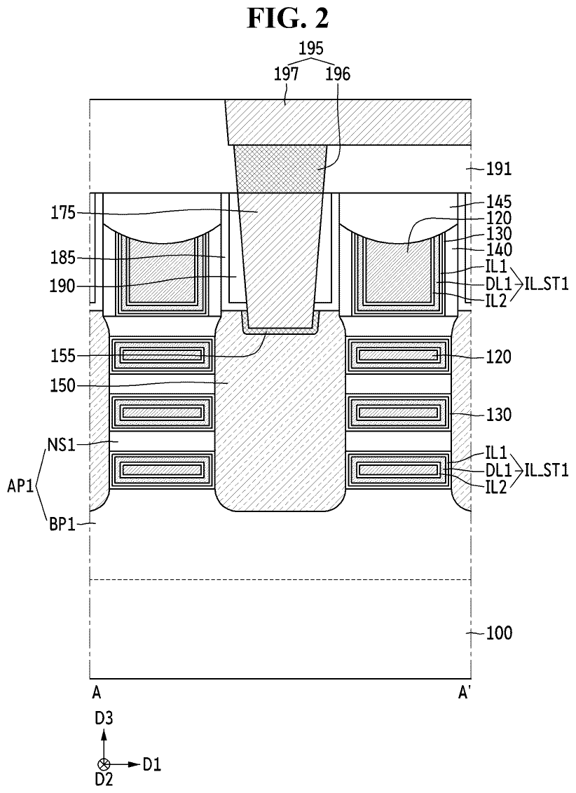

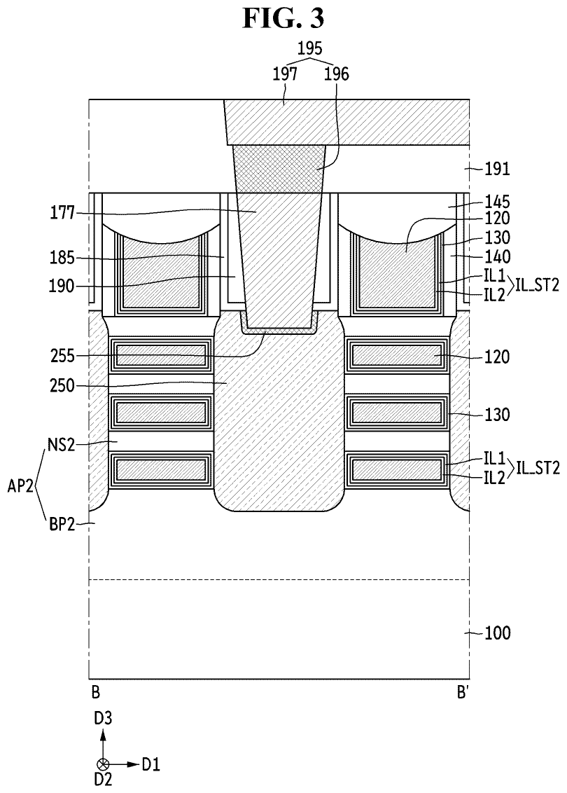

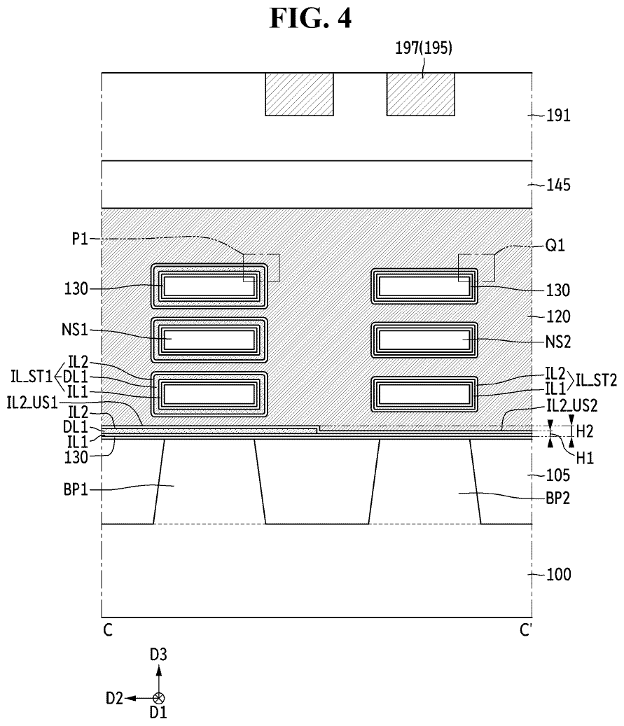

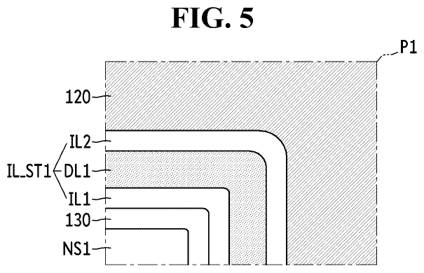

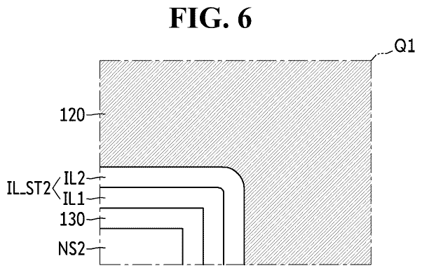

Hereinafter, the semiconductor device according to some embodiments of the present disclosure will be described with reference to FIGS. 1 to 6. FIG. 1 is an example layout or plan view illustrating a semiconductor device according to some embodiments. FIG. 2 is a cross-sectional view taken along line A-A′ of FIG. 1. FIG. 3 is a cross-sectional view taken along line B-B′ of FIG. 1. FIG. 4 is a cross-sectional view taken along line C-C′ of FIG. 1. FIG. 5 is an enlarged view illustrating a portion P1 of FIG. 4. FIG. 6 is an enlarged view illustrating a portion Q1 of FIG. 4.

Referring to FIGS. 1 to 6, the semiconductor device according to some embodiments may include a substrate 100, a first active pattern AP1, a second active pattern AP2, a field insulating layer 105, a gate electrode 120, a first source/drain pattern 150, a second source/drain pattern 250, a first insulating layer structure IL_ST1, a second insulating layer structure IL_ST2, an interfacial layer 130, a first source/drain contact 175, a second source/drain contact 177, and an upper wiring structure 195.

The substrate 100 may be a bulk silicon or a silicon-on-insulator (SOI). Alternatively, the substrate 100 may be a silicon substrate, or may include another material, for example, silicon germanium, silicon germanium on insulator (SGOI), indium antimonide, lead telluride, indium arsenide, indium phosphide, gallium arsenide, or gallium antimonide, but is not limited thereto.

The first active pattern AP1 and the second active pattern AP2 may be disposed on the substrate 100. Each of the first active pattern AP1 and the second active pattern AP2 may be extended to be long in a first direction D1. The first active pattern AP1 and the second active pattern AP2 may be adjacent to each other in a second direction D2. The first active pattern AP1 and the second active pattern AP2 may be disposed to be spaced apart from each other in the second direction D2. For example, the first direction D1 is a direction crossing or perpendicular to the second direction D2.

For example, the first active pattern AP1 may be a region in which an NMOS is formed, and the second active pattern AP2 may be a region in which a PMOS is formed. The first active pattern AP1 may include a channel region of the NMOS, and the second active pattern AP2 may include a channel region of the PMOS.

For example, the first active pattern AP1 and the second active pattern AP2 may be active regions included in a logic region. The first active pattern AP1 and the second active pattern AP2 may be active regions included in one standard cell.

The first active pattern AP1 may include a first lower pattern BP1 and a plurality of first sheet patterns NS1. The second active pattern AP2 may include a second lower pattern BP2 and a plurality of second sheet patterns NS2.

Each of the first lower pattern BP1 and the second lower pattern BP2 may be protruded from the substrate 100. Each of the first lower pattern BP1 and the second lower pattern BP2 may be extended to be long in the first direction D1. The first lower pattern BP1 may be spaced apart from the second lower pattern BP2 in the second direction D2.

The plurality of first sheet patterns NS1 may be disposed on the first lower pattern BP1. The plurality of first sheet patterns NS1 may be spaced apart from the first lower pattern BP1 in a third direction D3.

The plurality of second sheet patterns NS2 may be disposed on the second lower pattern BP2. The plurality of second sheet patterns NS2 may be spaced apart from the second lower pattern BP2 in the third direction D3.

The first sheet patterns NS1 may be sequentially disposed in the third direction D3. The respective first sheet patterns NS1 may be spaced apart from each other in the third direction D3. The second sheet patterns NS2 may be sequentially disposed in the third direction D3. The respective second sheet patterns NS2 may be spaced apart from each other in the third direction D3. In this case, the third direction D3 may be a direction crossing or perpendicular to the first direction D1 and the second direction D2. For example, the third direction D3 may be a thickness direction of the substrate 100.

Although three first sheet patterns NS1 and three second sheet patterns NS2 are shown as being disposed in the third direction D3, it is only for convenience of description, and the present disclosure is not limited thereto.

Each of the first lower pattern BP1 and the second lower pattern BP2 may be formed by etching a portion of the substrate 100 or may include an epitaxial layer grown from the substrate 100. Each of the first lower pattern BP1 and the second lower pattern BP2 may include silicon or germanium, which is an element semiconductor material.

In addition, each of the first lower pattern BP1 and the second lower pattern BP2 may include a compound semiconductor, for example, a group IV-IV compound semiconductor or a group III-V compound semiconductor.

The group IV-IV compound semiconductor may be a binary compound or ternary compound, which includes at least two of carbon (C), silicon (Si), germanium (Ge) or tin (Sn), or a compound including at least two of carbon (C), silicon (Si), germanium (Ge), or tin (Sn), which are doped with a group IV element.

The group III-V compound semiconductor may be, for example, one of a binary compound, a ternary compound, or a quaternary compound, which is formed by combination of at least one of aluminum (Al), gallium (Ga), or indium (In), which is a group III element, and one of phosphorus (P), arsenic (As), or antimony (Sb), which are group V elements.

Each of the first sheet patterns NS1 may include one of silicon or germanium, a Group IV-IV compound semiconductor or a Group III-V compound semiconductor, which is an elemental semiconductor material. Each of the second sheet patterns NS2 may include one of silicon or germanium, a Group IV-IV compound semiconductor or a Group III-V compound semiconductor, which is an elemental semiconductor material.

A width of the first sheet pattern NS1 in the second direction D2 may be increased or decreased in proportion to a width of the first lower pattern BP1 in the second direction D2. For example, although widths of the first sheet patterns NS1, which are stacked in the third direction D3, in the second direction D2 are shown to be the same, they are only for convenience of description and are not limited thereto. Unlike the shown example, as the first sheet patterns NS1 become far away from the first lower pattern BP1, the widths of the first sheet patterns NS1, which are stacked in the third direction D3, in the second direction D2 may be decreased.

A width of the second sheet pattern NS2 in the second direction D2 may be increased or decreased in proportion to a width of the second lower pattern BP2 in the second direction D2. For example, although widths of the second sheet patterns NS2, which are stacked in the third direction D3, in the second direction D2 are shown to be the same, they are only for convenience of description and are not limited thereto. Unlike the shown example, as the second sheet patterns NS2 become far away from the second lower pattern BP2, the widths of the second sheet patterns NS2, which are stacked in the third direction D3, in the second direction D2 may be decreased.

The field insulating layer 105 may be formed on the substrate 100. The field insulating layer 105 may be disposed on sidewalls of the first lower pattern BP1 and the second lower pattern BP2. The field insulating layer 105 is not disposed on an upper surface of the first lower pattern BP1. The field insulating layer 105 is not disposed on an upper surface of the second lower pattern BP2.

For example, the field insulating layer 105 may entirely cover, overlap or be on the sidewalls of the first lower pattern BP1 and the second lower pattern BP2. Unlike the shown example, the field insulating layer 105 may cover, overlap or be on a portion of the sidewall of the first lower pattern BP1 and a portion of the sidewall of the second lower pattern BP2. In this case, a portion of the first lower pattern BP1 may be more protruded in the third direction D3 than an upper surface of the field insulating layer 105.

Each of the first sheet patterns NS1 is disposed to be higher than the upper surface of the field insulating layer 105. Each of the second sheet patterns NS2 is disposed to be higher than the upper surface of the field insulating layer 105.

The field insulating layer 105 may include, for example, an oxide layer, a nitride layer, an oxynitride layer or their combination layer. The field insulating layer 105 is shown as a single layer but is only for convenience of description and is not limited thereto.

A plurality of gate electrodes 120 may be disposed on the substrate 100. The gate electrode 120 may be extended in the second direction D2. The gate electrodes 120 may be disposed to be spaced apart from each other in the first direction D1. The gate electrodes 120 may be adjacent to each other in the first direction D1. For example, the gate electrode 120 may be disposed on both sides of the first source/drain pattern 150 in the first direction D1. The gate electrode 120 may be disposed on both sides of the second source/drain pattern 250 in the first direction D1.

The gate electrode 120 may be disposed on the first active pattern AP1. The gate electrode 120 may be disposed on the second active pattern AP2. The gate electrode 120 may cross the first active pattern AP1 and the second active pattern AP2. The gate electrode 120 may surround each of the first sheet patterns NS1 and each of the second sheet patterns NS2. The gate electrode 120 may cover, overlap or be on each of the first sheet patterns NS1 and each of the second sheet patterns NS2.

The gate electrode 120 may be disposed between the first sheet patterns NS1, which are adjacent to each other in the third direction D3, and between the first lower pattern BP1 and the first sheet pattern NS1. The gate electrode 120 may be disposed between the second sheet patterns NS2, which are adjacent to each other in the third direction D3, and between the second lower pattern BP2 and the second sheet pattern NS2.

The gate electrode 120 may be disposed on the first lower pattern BP1. The first gate electrode 120 may cross the first lower pattern BP1. The gate electrode 120 may be disposed on the second lower pattern BP2. The second gate electrode 120 may cross the second lower pattern BP2.

The gate electrode 120 may include at least one of metal, a metal alloy, a conductive metal nitride, a metal silicide, a doped semiconductor material, a conductive metal oxide or a conductive metal oxynitride. The gate electrode 120 may include, but is not limited to, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or their combination. The conductive metal oxide and the conductive metal oxynitride may include, but are not limited to, oxidized forms of the materials described above.

The gate electrode 120 may be disposed on both sides of the first source/drain pattern 150 and the second source/drain pattern 250, which will be described later. The gate electrode 120 may be disposed at both sides of the first source/drain pattern 150 and the second source/drain pattern 250 in the first direction D1.

For example, the gate electrodes 120 disposed at both sides of the first source/drain pattern 150 and the second source/drain pattern 250 may be normal gate electrodes used as gates of transistors. For another example, the gate electrode 120 disposed at one side of the first source/drain pattern 150 and the second source/drain pattern 250 may be used as a gate of the transistor, but the gate electrode 120 disposed at the other side of the first source/drain pattern 150 and the second source/drain pattern 250 may be a dummy gate electrode.

The interfacial layer 130 may be extended along the upper surface of the field insulating layer 105, the upper surface of the first lower pattern BP1, and the upper surface of the second lower pattern BP2.

The interfacial layer 130 may be interposed between the plurality of first sheet patterns NS1 and the gate electrode 120. The interfacial layer 130 may surround any of the plurality of first sheet patterns NS1. The interfacial layer 130 may be disposed along a circumference or perimeter of the plurality of first sheet patterns NS1. Herein, reference to a “circumference” of an element does not require the element to be circular or elliptical, and is meant to encompass a perimeter of the element in an embodiment wherein the element is polygonal.

The interfacial layer 130 may be interposed between the plurality of second sheet patterns NS2 and the gate electrode 120. The interfacial layer 130 may surround the plurality of second sheet patterns NS2. The interfacial layer 130 may be disposed along a circumference of the plurality of second sheet patterns NS2.

The interfacial layer 130 may include at least one of, for example, silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), or their combination.

A gate spacer 140 may be disposed on a sidewall of the gate electrode 120. The gate spacer 140 may not be disposed between the first lower pattern BP1 and the first sheet pattern NS1 and between the first sheet patterns NS1 adjacent to each other in the third direction D3. The gate spacer 140 may not be disposed between the second lower pattern BP2 and the second sheet pattern NS2 and between the second sheet patterns NS2 adjacent to each other in the third direction D3.

The gate spacer 140 may include at least one of, for example, silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), or their combination.

A gate capping pattern 145 may be disposed on the gate electrode 120 and the gate spacer 140. An upper surface of the gate capping pattern 145 may be disposed on the same plane as an upper surface of a first interlayer insulating layer 190, but the present disclosure is not limited thereto. Unlike the shown example, the gate capping pattern 145 may be disposed between the gate spacers 140.

The gate capping pattern 145 may include at least one of, for example, silicon nitride (SiN), silicon oxynitride (SiON), silicon carbide (SiCN), silicon oxynitride (SiOCN), or their combination. The gate capping pattern 145 may include a material having etch selectivity with respect to the first interlayer insulating layer 190.

The first insulating layer structure IL_ST1 may be interposed between the first sheet pattern NS1 and the gate electrode 120. The first insulating layer structure IL_ST1 may be interposed between the interfacial layer 130 and the gate electrode 120. The first insulating layer structure IL_ST1 may be disposed along the circumference of the first sheet pattern NS1. The first insulating layer structure IL_ST1 may be disposed along a circumference of the interfacial layer 130.

The first insulating layer structure IL_ST1 may include a first insulating layer IL1, a first insertion insulating layer DL1, and a second insulating layer IL2. The first insulating layer IL1, the first insertion insulating layer DL1 and the second insulating layer IL2 may be sequentially disposed on the interfacial layer 130.

The first insulating layer IL1 may be disposed between the first sheet pattern NS1 and the gate electrode 120 along the circumference of the interfacial layer 130. The first insulating layer IL1 may be disposed along a circumference of an outer wall of the interfacial layer 130. The first insulating layer IL1 may be in contact with the interfacial layer 130.

The first insertion insulating layer DL1 may be disposed between the first sheet pattern NS1 and the gate electrode 120 along a circumference of the first insulating layer IL1. The first insertion insulating layer DL1 may be disposed along a circumference of an outer wall of the first insulating layer IL1.

The second insulating layer IL2 may be disposed between the first sheet pattern NS1 and the gate electrode 120 along a circumference of the first insertion insulating layer DL1. The second insulating layer IL2 may be interposed between the first insertion insulating layer DL1 and the gate electrode 120. The second insulating layer IL2 may be disposed along a circumference of an outer wall of the first insertion insulating layer DL1.

The first insulating layer IL1 and the second insulating layer IL2 may include the same material. The first insulating layer IL1 and the gate insulating layer IL2 may include silicon oxide, silicon-germanium oxide, germanium oxide, silicon oxynitride, silicon nitride or a high dielectric constant material having a dielectric constant greater than that of silicon oxide. For example, the high dielectric constant material may include at least one of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide or lead zinc niobate.

Each of the first insulating layer IL1 and the second insulating IL2 is shown as a single layer, but this is for convenience of description and is not limited thereto. Each of the first insulating layer IL1 and the second insulating layer IL2 may include a plurality of layers.

The semiconductor device according to some embodiments may include a negative capacitance (NC) FET based on a negative capacitor. For example, the first insulating layer IL1 and the second insulating layer IL2 may include a ferroelectric material layer having ferroelectric characteristics and a paraelectric material layer having paraelectric characteristics.

The ferroelectric material layer may have a negative capacitance, and the paraelectric material layer may have a positive capacitance. For example, when two or more capacitors are connected in series, and the capacitance of each capacitor has a positive value, the total capacitance is more reduced than the capacitance of each individual capacitor. On the other hand, when at least one of capacitances of two or more capacitors connected in series has a negative value, the total capacitance may have a positive value and may be greater than an absolute value of each individual capacitance.

When a ferroelectric material layer having a negative capacitance and a paraelectric material layer having a positive capacitance are connected in series, the total capacitance value of the ferroelectric material layer and the paraelectric material layer, which are connected in series, may be increased. Based on the total capacitance value that is increased, a transistor having a ferroelectric material layer may have a subthreshold swing (SS) less than 60 mV/decade at a room temperature.

The ferroelectric material layer may have ferroelectric characteristics. The ferroelectric material layer may include at least one of, for example, hafnium oxide, hafnium zirconium oxide, barium strontium titanium oxide, barium titanium oxide, or lead zirconium titanium oxide. In this case, for example, the hafnium zirconium oxide may be a material doped with zirconium (Zr) in hafnium oxide. For another example, the hafnium zirconium oxide may be a compound of hafnium (Hf) and zirconium (Zr) and oxygen (O).

The ferroelectric material layer may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). A type of the dopant included in the ferroelectric material layer may be varied depending on the ferroelectric material of the ferroelectric material layer.

When the ferroelectric material layer includes hafnium oxide, the dopant included in the ferroelectric material layer may include at least one of gadolinium (Gd), silicon (Si), zirconium (Zr), aluminum (Al), or yttrium (Y).

When the dopant is aluminum (Al), the ferroelectric material layer may include aluminum of 3 at % to 8 at % (atomic %). In this case, a ratio of the dopant may be a ratio of aluminum to a sum of hafnium and aluminum.

When the dopant is silicon (Si), the ferroelectric material layer may include silicon of 2 at % to 10 at %. When the dopant is yttrium (Y), the ferroelectric material layer may include yttrium of 2 at % to 10 at %. When the dopant is gadolinium (Gd), the ferroelectric material layer may include gadolinium of 1 at % to 7 at %. When the dopant is zirconium (Zr), the ferroelectric material layer may include zirconium of 50 at % to 80 at %.

The paraelectric material layer may have paraelectric characteristics. The paraelectric material layer may include at least one of, for example, silicon oxide or metal oxide having a high dielectric constant. The metal oxide included in the paraelectric material layer may include, but is not limited to, at least one of hafnium oxide, zirconium oxide, or aluminum oxide.

The ferroelectric material layer and the paraelectric material layer may include the same material. Although the ferroelectric material layer has ferroelectric characteristics, the paraelectric material layer may not have ferroelectric characteristics. For example, when the ferroelectric material layer and the paraelectric material layer include hafnium oxide, a crystal structure of hafnium oxide included in the ferroelectric material layer is different from that of hafnium oxide included in the paraelectric material layer.

The ferroelectric material layer may have a thickness having ferroelectric characteristics. The thickness of the ferroelectric material layer may be, for example, 0.5 nm to 10 nm, but is not limited thereto. Since a threshold thickness indicating ferroelectric characteristics may be varied depending on each ferroelectric material, the thickness of the ferroelectric material layer may be varied depending on the ferroelectric material.

For example, the first insulating layer IL1 and the second insulating layer IL2 may include one ferroelectric material layer. For another example, the first insulating layer IL1 and the second insulating layer IL2 may include a plurality of ferroelectric material layers spaced apart from each other. The first insulating layer IL1 and the second insulating layer IL2 may have a stacked layer structure in which a plurality of ferroelectric material layers and a plurality of paraelectric material layers are alternately stacked.

The first insertion insulating layer DL1 may include lanthanum (La). For example, the first insertion insulating layer DL1 may include lanthanum oxide (LaO). In this case, the chemical formula “LaO” merely represents an element included in the compound and does not represent a stoichiometric relationship between the elements included in the chemical formula.

The second insulating layer structure IL_ST2 may be interposed between the second sheet pattern NS2 and the gate electrode 120. The second insulating layer structure IL_ST2 may be interposed between the interfacial layer 130 and the gate electrode 120. The second insulating layer structure IL_ST2 may be disposed along the circumference of the second sheet pattern NS2. The second insulating layer structure IL_ST2 may be disposed along the circumference of the interfacial layer 130.

The second insulating layer structure IL_ST2 may include a first insulating layer IL1 and a second insulating layer IL2. The first insulating layer IL1 and the second insulating layer IL2 may be sequentially disposed on the interfacial layer 130.

The first insulating layer IL1 may be disposed between the second sheet pattern NS2 and the gate electrode 120 along the circumference of the interfacial layer 130.

The second insulating layer IL2 may be disposed between the second sheet pattern NS2 and the gate electrode 120 along the circumference of the first insulating layer IL1.

The first insulating layer IL1 may be disposed on the upper surface of the field insulating layer 105, the upper surface of the first lower pattern BP1, and the upper surface of the second lower pattern BP2. The first insulating layer IL1 may be disposed on the interfacial layer 130.

The first insertion insulating layer DL1 may be disposed on the first lower pattern BP1. The first insertion insulating layer DL1 may overlap the first lower pattern BP1 in the third direction D3. The first insertion insulating layer DL1 may not overlap the second lower pattern BP2 in the third direction D3.

The second insulating layer IL2 may be disposed on the first lower pattern BP1 and the second lower pattern BP2. The second insulating layer IL2 may be extended on the first lower pattern BP1 along an upper surface of the first insertion insulating layer DL1. The second insulating layer IL2 may be extended on the second lower pattern BP2 along an upper surface of the first insulating layer IL1.

In the third direction D3, the first insulating layer IL1, the second insertion insulating layer DL2 and the second insulating layer IL2 may be sequentially disposed on the first lower pattern BP1. In the third direction D3, the first insulating layer IL1 and the second insulating layer IL2 may be sequentially disposed on the second lower pattern BP2. A level in the third direction of the second insulating layer IL2, which overlaps the first lower pattern BP1 in the third direction D3, may be greater than a level of the second insulating layer IL2, which overlaps the second lower pattern BP2 in the third direction D3. For example, a height H2 of a first upper surface IL2_US1 of the second insulating layer IL2, which overlaps the first lower pattern BP1 in the third direction D3, may be greater than a height H1 of a second upper surface IL2_US2 of the second insulating layer IL2, which overlaps the second lower pattern BP2 in the third direction D3.

The first source/drain pattern 150 may be disposed on the first active pattern AP1. The first source/drain pattern 150 may be disposed on the first lower pattern BP1.

The first source/drain pattern 150 may be disposed on the first sheet pattern NS1 and the second insulating layer IL2. The first source/drain pattern 150 may be in contact with the second insulating layer IL2. The first source/drain pattern 150 may be connected to the first sheet pattern NS1.

The first source/drain pattern 150 may be disposed on a side of the gate electrode 120. The first source/drain pattern 150 may be disposed between gate electrodes 120 adjacent to each other in the first direction D1. For example, the first source/drain pattern 150 may be disposed on both sides of the gate electrode 120. Unlike the shown example, the first source/drain pattern 150 may be disposed on one side of the gate electrode 120 and may not be disposed on the other side of the gate electrode 120.

The first source/drain pattern 150 may be included in a source/drain of a transistor, which uses the first sheet pattern NS1 as a channel region.

The second source/drain pattern 250 may be spaced apart from the first source/drain pattern 150 in the second direction D2. The second source/drain pattern 250 may be disposed on the second active pattern AP2. The second source/drain pattern 250 may be disposed on the second lower pattern BP2.

The second source/drain pattern 250 may be disposed on the second sheet pattern NS2 and the second insulating layer IL2. The second source/drain pattern 250 may be in contact with the second insulating layer IL2. The second source/drain pattern 250 may be connected to the second sheet pattern NS2.

The second source/drain pattern 250 may be disposed on sides of the gate electrode 120. The second source/drain pattern 250 may be disposed between the gate electrodes 120 adjacent to each other in the first direction D1. For example, the second source/drain pattern 250 may be disposed on both sides of the gate electrode 120. Unlike the shown example, the second source/drain pattern 250 may be disposed on one side of the gate electrode 120 and may not be disposed on the other side of the gate electrode 120.

The first and second source/drain patterns 150 and 250 may include, for example, silicon or germanium, which is an element semiconductor material. For example, the first and second source/drain patterns 150 and 250 may include, for example, a binary compound or ternary compound, which includes at least two of carbon (C), silicon (Si), germanium (Ge) or tin (Sn), or a compound including at least two of carbon (C), silicon (Si), germanium (Ge) or tin (Sn), which are doped with a group IV element. Each of the first and second source/drain patterns 150 and 250 may include an epitaxial layer made of a semiconductor.

The first and second source/drain patterns 150 and 250 may include a dopant doped into a semiconductor material.

A source/drain etching stop layer 185 may be disposed on the first and second source/drain patterns 150 and 250. The source/drain etching stop layer 185 may be extended along an outer sidewall of the gate spacer 140. The source/drain etching stop layer 185 may be extended along profiles of the first and second source/drain patterns 150 and 250.

The source/drain etching stop layer 185 may include a material having etch selectivity with respect to the first interlayer insulating layer 190 that will be described later. The source/drain etching stop layer 185 may include at least one of, for example, silicon nitride (SiN), silicon oxynitride (SiON), silicon oxycarbonitride (SiOCN), silicon boron nitride (SiBN), silicon oxyboron nitride (SiOBN), silicon oxycarbide (SiOC), or their combination.

The first interlayer insulating layer 190 may be disposed on the source/drain etching stop layer 185. The first interlayer insulating layer 190 may be disposed on the first and second source/drain patterns 150 and 250. The first interlayer insulating layer 190 may not cover or may not overlap the upper surface of the first gate capping pattern 145. For example, an upper surface of the first interlayer insulating layer 190 may be disposed on the same plane as the upper surface of the first gate capping pattern 145.

The first interlayer insulating layer 190 may include at least one of, for example, silicon oxide, silicon nitride, silicon oxynitride or a low dielectric constant material. The low dielectric constant material may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylCycloTetraSiloxane (OMCTS), HexaMethylDiSiloxane (HMDS), TriMethylSilyl Borate (TMSB), DiAcetoxyDitertiaryButoxySiloxane (DADBS), TriMethylSilyl Phosphate (TMSP), PolyTetraFluoroEthylene (PTFE), Tonen SilaZen (TOSZ), Fluoride Silicate Glass (FSG), polyimide nanofoams such as polypropylene oxide, Carbon Doped silicon Oxide (CDO), Organo Silicate Glass (OSG), SiLK, Amorphous Fluorinated Carbon, silica aerogels, silica xerogels, mesoporous silica, or their combination, but the is not limited thereto.

The first source/drain contact 175 may be disposed on the first source/drain pattern 150. The first source/drain contact 175 is connected to the first source/drain pattern 150. The first source/drain contact 175 may be connected to the first source/drain pattern 150 by passing through the first interlayer insulating layer 190 and the source/drain etching stop layer 185.

A first metal silicide film 155 may be disposed between the first source/drain contact 175 and the first source/drain pattern 150.

The second source/drain contact 177 may be disposed on the second source/drain pattern 250. The second source/drain contact 177 is connected to the second source/drain pattern 250. The second source/drain contact 177 may be connected to the second source/drain pattern 250 by passing through the first interlayer insulating layer 190 and the source/drain etching stop layer 185.

A second metal silicide film 255 may be disposed between the second source/drain contact 177 and the second source/drain pattern 250.

Although the first source/drain contact 175 and the second source/drain contact 177 are shown as a single layer, this is only for convenience of description, and the present disclosure is not limited thereto. The first and second source/drain contacts 175 and 177 may include at least one of, for example, metal, a metal alloy, a conductive metal nitride, a conductive metal carbide, a conductive metal oxide, a conductive metal carbonitride, or a two-dimensional (2D) material. The first and second metal silicide films 155 and 255 may include metal silicide.

The second interlayer insulating layer 191 is disposed on the first interlayer insulating layer 190. The second interlayer insulating layer 191 may include at least one of, for example, silicon oxide, silicon nitride, silicon oxynitride, or a low dielectric constant material.

The upper wiring structure 195 may be disposed in the second interlayer insulating layer 191. The upper wiring structure 195 may include a via plug 196 and a wiring line 197.

The upper wiring structure 195 may be connected to the first and second source/drain patterns 150 and 250.

Each of the via plug 196 and the wiring line 197 may include at least one of, for example, metal, a metal alloy, a conductive metal nitride, a conductive metal carbide, a conductive metal oxide, a conductive metal carbonitride or a two-dimensional (2D) material.

Although each of the via plug 196 and the wiring line 197 is shown as a single conductive layer structure, this is only for convenience of description, and the present disclosure is not limited thereto. Unlike the shown example, for example, at least one of the via plug 196 or the wiring line 197 may have a multi-conductive layer structure. As another example, the upper wiring structure 195 may have an integrated structure in which there is no division of a boundary line between the via plug 196 and the wiring line 197.

NMOS and PMOS transistors may be manufactured using different work function metals. That is, different work function metals may be used to implement a threshold voltage V_{T} of each of the NMOS and PMOS transistors. However, as the size of the transistor is reduced, it is difficult to pattern different work function metals in each of the NMOS and PMOS transistors.

The semiconductor device according to some embodiments of the present disclosure may include a first insulating layer structure IL_ST1 and a second insulating layer structure IL_ST2. The threshold voltages of the NMOS and PMOS transistors may be adjusted using the first insulating layer structure IL_ST1 and the second insulating layer structure IL_ST2. Since the threshold voltages of NMOS and PMOS transistors are adjusted using the first insulating layer structure IL_ST1 and the second insulating layer structure IL_ST2, the same work function metal may be used for the NMOS and PMOS transistors.

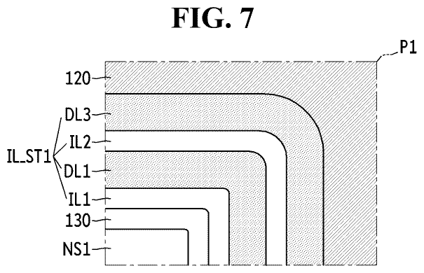

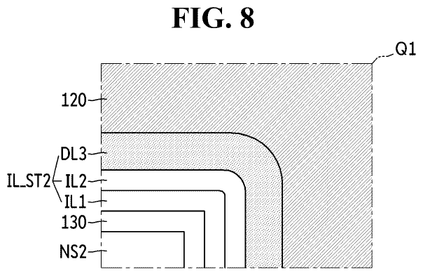

FIGS. 7 and 8 are views illustrating a semiconductor device according to some embodiments of the present disclosure. FIG. 7 is an enlarged view illustrating a portion P1 of FIG. 4. FIG. 8 is an enlarged view illustrating a portion Q1 of FIG. 4. For convenience of description, redundant portions of those described with reference to FIGS. 1 to 6 will be briefly described or omitted.

Referring to FIGS. 7 and 8, the first insulating layer structure IL_ST1 and the second insulating layer structure IL_ST2 may further include a third insertion insulating layer DL3.

The first insulating layer structure IL_ST1 may include a first insulating layer IL1, a first insertion insulating layer DL1, a second insulating layer IL2 and a third insertion insulating layer DL3. The second insulating layer structure IL_ST2 may include a first insulating layer IL1, a second insulating layer IL2 and a third insertion insulating layer DL3. Descriptions of the first insulating layer IL1, the first insertion insulating layer DL1 and the second insulating layer IL2 may be substantially the same as those of FIGS. 1 to 6.

The third insertion insulating layer DL3 may be disposed between the first sheet pattern NS1 and the gate electrode 120 along a circumference of the second insulating layer IL2. The third insertion insulating layer DL3 may be disposed between the second sheet pattern NS2 and the gate electrode 120 along the circumference of the second insulating layer IL2.

The third insertion insulating layer DL3 may include lanthanum (La). For example, the third insertion insulating layer DL3 may include lanthanum oxide (LaO).

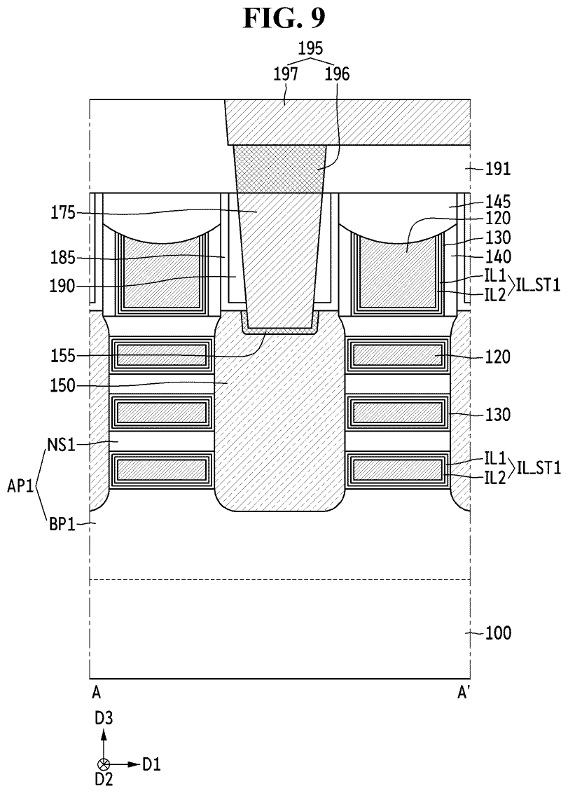

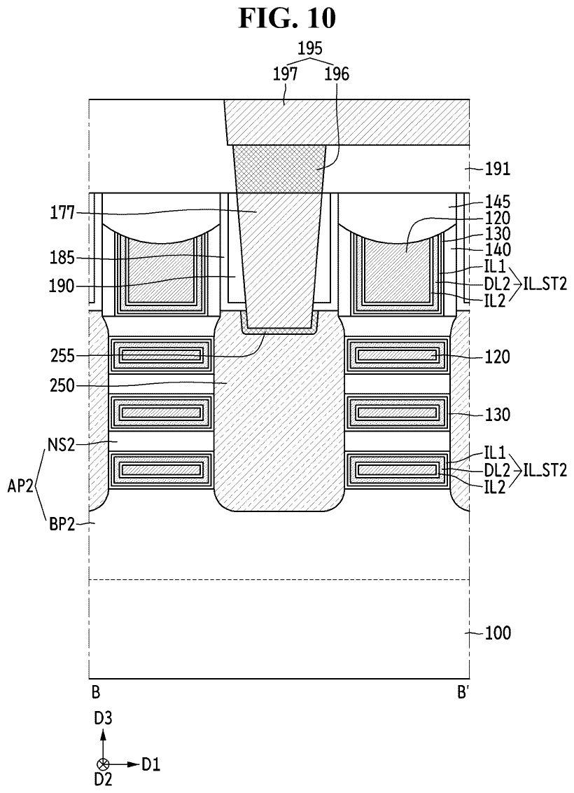

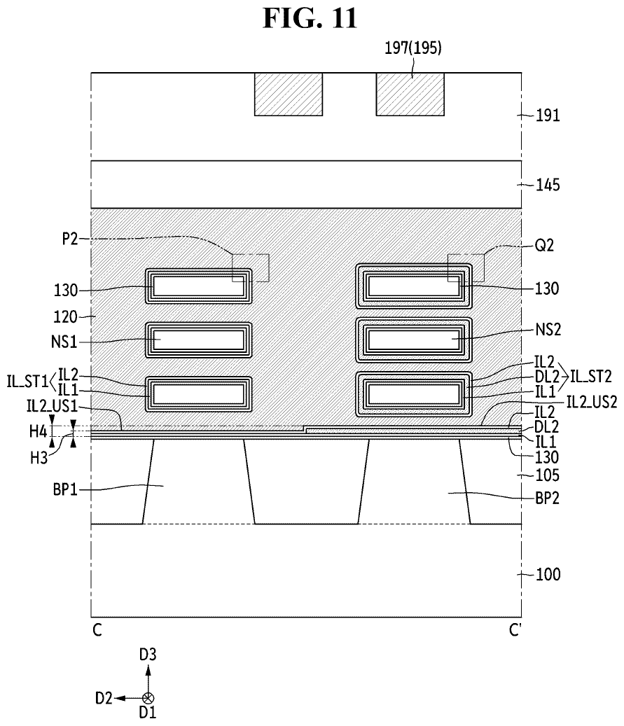

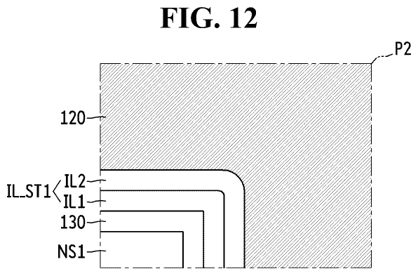

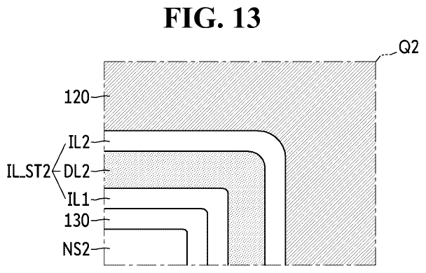

FIGS. 9 to 13 are views illustrating a semiconductor device according to some embodiments of the present disclosure. FIG. 12 is an enlarged view illustrating a portion P2 of FIG. 11. FIG. 13 is an enlarged view illustrating a portion Q2 of FIG. 11. For convenience of description, redundant portions of those described with reference to FIGS. 1 to 6 will be briefly described or omitted.

Referring to FIGS. 9 to 13, the first insulating layer structure IL_ST1 may be interposed between the first sheet pattern NS1 and the gate electrode 120. The first insulating layer structure IL_ST1 may be interposed between the interfacial layer 130 and the gate electrode 120. The first insulating layer structure IL_ST1 may be disposed along the circumference of the first sheet pattern NS1.

The first insulating layer structure IL_ST1 may include a first insulating layer IL1 and a second insulating layer IL2. Unlike FIGS. 1 to 6, the first insulating layer structure IL_ST1 may not include the first insertion insulating layer DL1. The first insulating layer IL1 and the second insulating layer IL2 may be sequentially disposed on the interfacial layer 130.

The first insulating layer IL1 may be disposed between the first sheet pattern NS1 and the gate electrode 120 along the circumference of the interfacial layer 130.

The second insulating layer IL2 may be disposed between the first sheet pattern NS1 and the gate electrode 120 along the circumference of the first insulating layer IL1.

The second insulating layer structure IL_ST2 may be interposed between the second sheet pattern NS2 and the gate electrode 120. The second insulating layer structure IL_ST2 may be interposed between the interfacial layer 130 and the gate electrode 120. The second insulating layer structure IL_ST2 may be disposed along the circumference of the second sheet pattern NS2. The second insulating layer structure IL_ST2 may be disposed along the circumference of the interfacial layer 130.

The second insulating layer structure IL_ST2 may include a first insulating layer IL1, a second insertion insulating layer DL2, and a second insulating layer IL2. The first insulating layer IL1, the second insertion insulating layer DL2 and the second insulating layer IL2 may be sequentially disposed on the interfacial layer 130.

The first insulating layer IL1 may be disposed between the second sheet pattern NS2 and the gate electrode 120 along the circumference of the interfacial layer 130. The first insulating layer IL1 may be disposed along the circumference of the outer wall of the interfacial layer 130.

The second insertion insulating layer DL2 may be disposed between the second sheet pattern NS2 and the gate electrode 120 along the circumference of the first insulating layer IL1. The second insertion insulating layer DL2 may be disposed along the circumference of the outer wall of the first insulating layer IL1.

The second insertion insulating layer DL2 may include aluminum (Al). For example, the second insertion insulating layer DL2 may include aluminum oxide (AlO).

The second insulating layer IL2 may be disposed between the second sheet pattern NS2 and the gate electrode 120 along a circumference of the second insertion insulating layer DL2.

The second insulating layer IL2 may be interposed between the second insertion insulating layer DL2 and the gate electrode 120. The second insulating layer IL2 may be disposed along a circumference of an outer wall of the second insertion insulating layer DL2.

The first insulating layer IL1 may be disposed on the upper surface of the field insulating layer 105, the upper surface of the first lower pattern BP1, and the upper surface of the second lower pattern BP2. The first insulating layer IL1 may be disposed on the interfacial layer 130.

The second insertion insulating layer DL2 may be disposed on the second lower pattern BP2. The second insertion insulating layer DL2 may overlap the second lower pattern BP2 in the third direction D3. The second insertion insulating layer DL2 may not overlap the first lower pattern BP1 in the third direction D3.

The second insulating layer IL2 may be disposed on the first lower pattern BP1 and the second lower pattern BP2. The second insulating layer IL2 may be extended on the second lower pattern BP2 along the upper surface of the second insertion insulating layer DL2. The second insulating layer IL2 may be extended on the first lower pattern BP1 along the upper surface of the first insulating layer IL1.

In the third direction D3, the first insulating layer IL1 and the second insulating layer IL2 may be sequentially disposed on the first lower pattern BP1. In the third direction D3, the first insulating layer IL1, the second insertion insulating layer DL2 and the second insulating layer IL2 may be sequentially disposed on the second lower pattern BP2. A level of the second insulating layer IL2 that overlaps the second lower pattern BP2 in the third direction D3 may be greater than a level of the second insulating layer IL2 that overlaps the first lower pattern BP1 in the third direction D3. For example, a height H4 of the second upper surface IL2_US2 of the second insulating layer IL2, which overlaps the second lower pattern BP2 in the third direction D3, may be greater than a height H3 of the first upper surface IL2_US1 of the second insulating layer IL2, which overlaps the first lower pattern BP1 in the third direction D3.

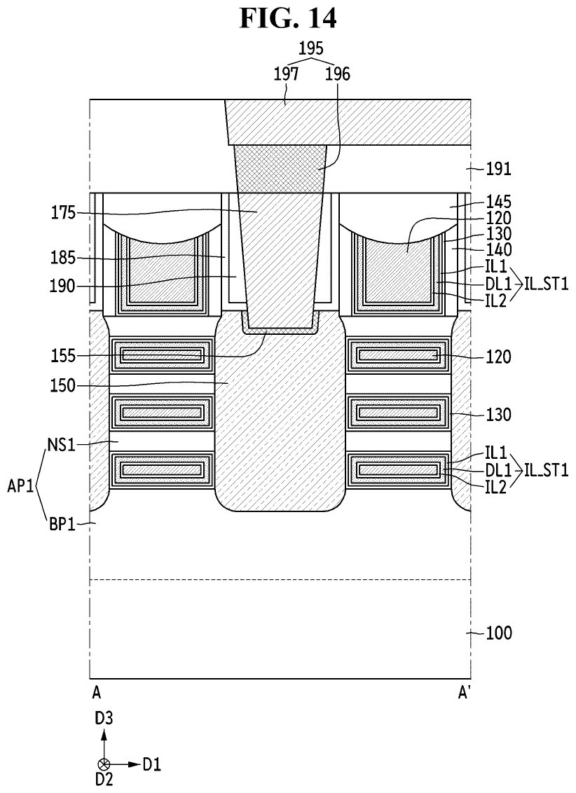

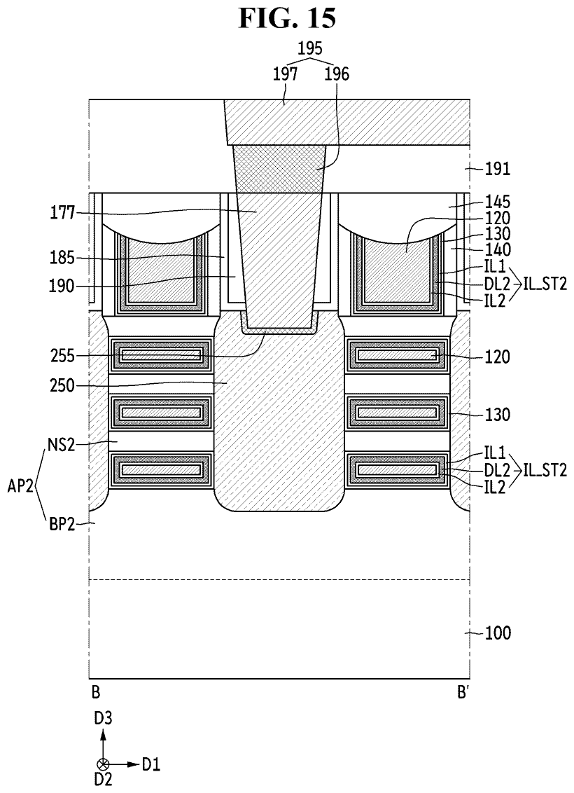

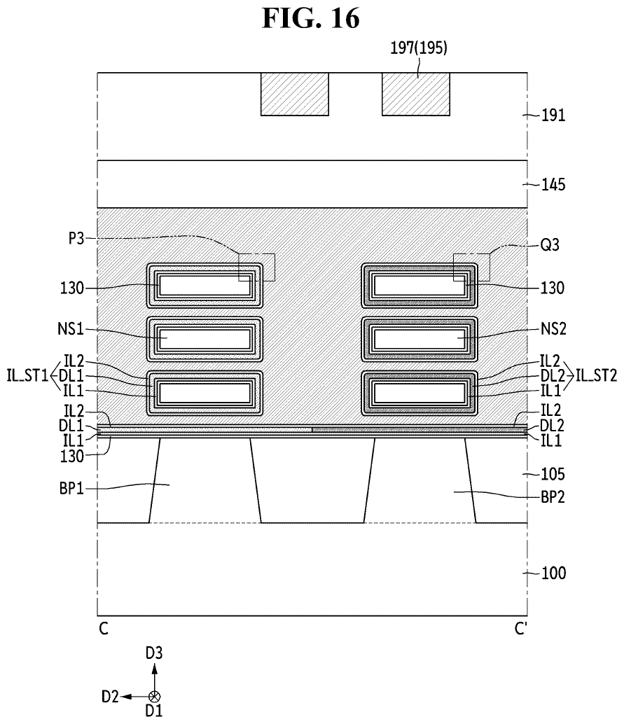

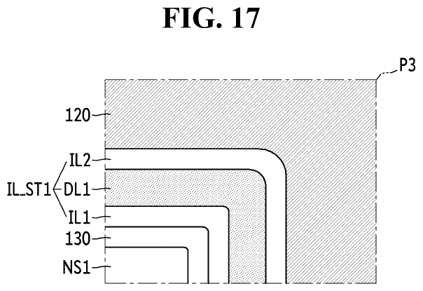

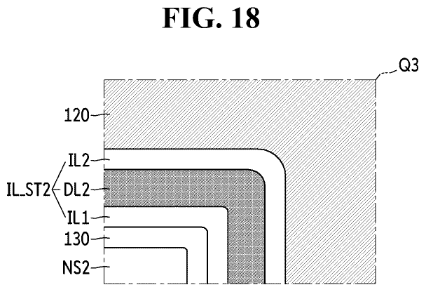

FIGS. 14 to 18 are views illustrating a semiconductor device according to some embodiments of the present disclosure. For convenience of description, redundant portions of those described with reference to FIGS. 1 to 13 will be briefly described or omitted.

Referring to FIGS. 14 to 18, the first insulating layer structure IL_ST1 may include a first insulating layer IL1, a first insertion insulating layer DL1, and a second insulating layer IL2. The second insulating layer structure IL_ST2 may include a first insulating layer IL1, a second insertion insulating layer DL2, and a second insulating layer IL2.

The first insulating layer structure IL_ST1 may be disposed between the first sheet pattern NS1 and the gate electrode 120. The first insulating layer structure IL_ST1 may include a first insulating layer IL1 disposed along the circumference of the interfacial layer 130, a first insertion insulating layer DL1 disposed along the circumference of the first insulating layer IL1, and a second insulating layer IL2 disposed along the circumference of the first insertion insulating layer DL1. The first insertion insulating layer DL1 may include lanthanum oxide.

The second insulating layer structure IL_ST2 may be disposed between the second sheet pattern NS2 and the gate electrode 120. The second insulating layer structure IL_ST2 may include a first insulating layer IL1 disposed along the circumference of the interfacial layer 130, a second insertion insulating layer DL2 disposed along the circumference of the first insulating layer IL1, and a second insulating layer IL2 disposed along the circumference of the second insertion insulating layer DL2. The second insertion insulating layer DL2 may include aluminum oxide.

A level of the first insertion insulating layer DL1 that overlaps the first lower pattern BP1 in the third direction D3 may be the same as a level of the second insertion insulating layer DL2 that overlaps the second lower pattern BP2 in the third direction D3. For example, a height of the upper surface of the first insertion insulating layer DL1 that overlaps the first lower pattern BP1 in the third direction D3 may be the same as a height of the upper surface of the second insertion insulating layer DL2 that overlaps the second lower pattern BP2 in the third direction D3.

Since the first insulating layer structure IL_ST1 includes a first insertion insulating layer DL1 including lanthanide oxide and the second insulating layer structure IL_ST2 includes a second insertion insulating layer DL2 including aluminum oxide, an NMOS may be formed for the first active pattern AP1, and a PMOS may be formed for the second active pattern AP2.

Since the first insulating layer structure IL_ST1 includes the first insertion insulating layer DL1 including lanthanum oxide and the second insulating layer structure IL_ST2 includes the second insertion insulating layer DL2 including aluminum oxide, a work function of each of the first active pattern AP1 and the second active pattern AP2 may be adjusted.

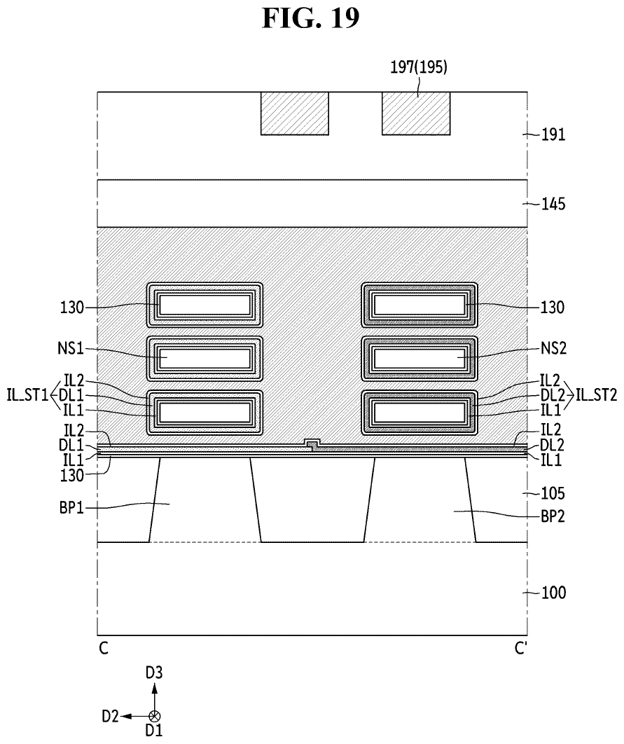

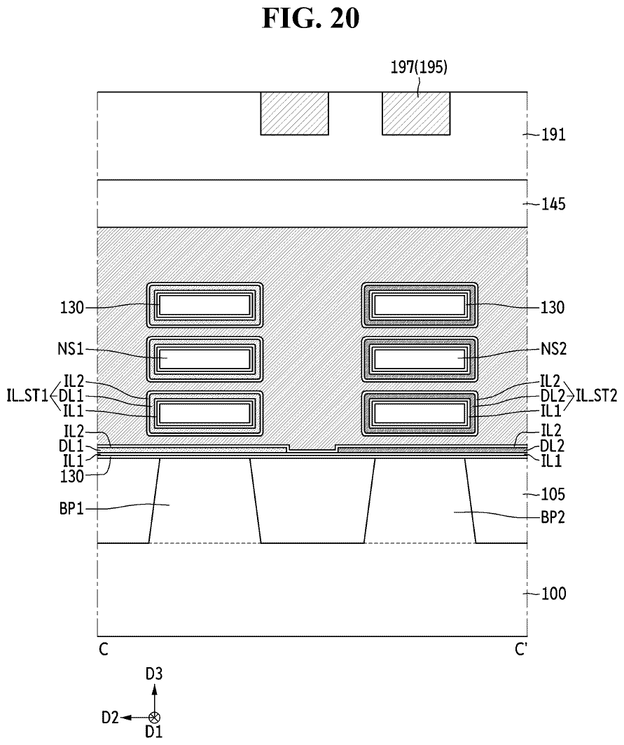

FIG. 19 is a view illustrating a semiconductor device according to some embodiments of the present disclosure. FIG. 20 is a view illustrating a semiconductor device according to some embodiments of the present disclosure. For convenience of description, redundant portions of those described with reference to FIGS. 14 to 18 will be briefly described or omitted.

Referring to FIG. 19, the first insertion insulating layer DL1 may be disposed on the first lower pattern BP1. The second insertion insulating layer DL2 may be disposed on the second lower pattern BP2. The first insertion insulating layer DL1 and the second insertion insulating layer DL2 may be disposed on the first insulating layer IL1.

A portion of the first insertion insulating layer DL1 and a portion of the second insertion insulating layer DL2 may overlap each other in the third direction D3 on the field insulating layer 105 disposed between the first lower pattern BP1 and the second lower pattern BP2. A portion of the second insertion insulating layer DL2 may cover, overlap or be on a portion of the upper surface of the first insertion insulating layer DL1 on the field insulating layer 105 disposed between the first lower pattern BP1 and the second lower pattern BP2.

The second insulating layer IL2 may be disposed on the first insertion insulating layer DL1 and the second insertion insulating layer DL2 on the upper surface of the field insulating layer 105, the upper surface of the first lower pattern BP1 and the upper surface of the second lower pattern BP2. The second insulating layer IL2 may be extended along the upper surface of the first insertion insulating layer DL1 and the upper surface of the second insertion insulating layer DL2. The second insulating layer IL2 may be protruded in the third direction D3 on the field insulating layer 105 disposed between the first lower pattern BP1 and the second lower pattern BP2.

Referring to FIG. 20, the first insertion insulating layer DL1 and the second insertion insulating layer DL2 may be spaced apart from each other in the first direction D1 on the upper surface of the field insulating layer 105, the upper surface of the first lower pattern BP1 and the upper surface of the second lower pattern BP2. The first insertion insulating layer DL1 and the second insertion insulating layer DL2 may not be in contact with each other on the upper surface of the field insulating layer 105.

The second insulating layer IL2 may be disposed on the upper surface of the first insertion insulating layer DL1 and the upper surface of the second insertion insulating layer DL2. A portion of the second insulating layer IL2 may be disposed between the first insertion insulating layer DL1 and the second insertion insulating layer DL2 on the field insulating layer 105 disposed between the first lower pattern BP1 and the second lower pattern BP2. The second insulating layer IL2 may have a concave shape but is not limited thereto.

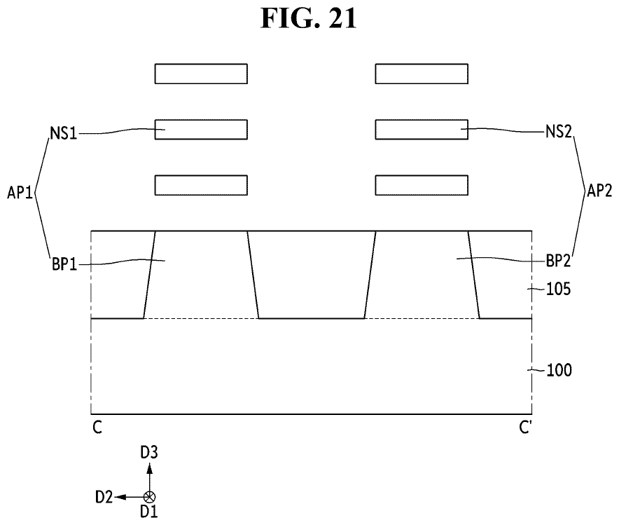

FIGS. 21 to 27 are views illustrating intermediate steps to describe a method for fabricating a semiconductor device according to some embodiments. For convenience of description, redundant portions of those described with reference to FIGS. 1 to 6 will be briefly described or omitted.

Referring to FIG. 21, the first active pattern AP1 and the second active pattern AP2 are formed on the substrate 100.

The first active pattern AP1 may include a first lower pattern BP1 and a plurality of first sheet patterns NS1. The first lower pattern BP1 may be protruded from the substrate 100 in the third direction D3. The plurality of first sheet patterns NS1 may be disposed to be spaced apart from the first lower pattern BP1 in the third direction D3.

The second active pattern AP2 may include a second lower pattern BP2 and a plurality of second sheet patterns NS2. The second lower pattern BP2 may be protruded from the substrate 100 in the third direction D3. The plurality of second sheet patterns NS2 may be disposed to be spaced apart from the second lower pattern BP2 in the third direction D3.

The field insulating layer 105 may be formed on the substrate 100. The field insulating layer 105 may be formed on the sides of the first lower pattern BP1 and the second lower pattern BP2. The field insulating layer 105 does not cover or does not overlap the upper surface of the first lower pattern BP1 and the upper surface of the second lower pattern BP2.

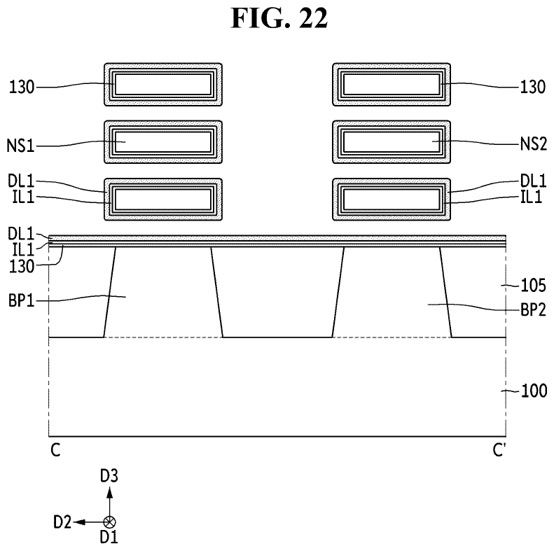

Referring to FIG. 22, the interfacial layer 130, the first insulating layer IL1 and the first insertion insulating layer DL1 are sequentially formed on the upper surface of the first lower pattern BP1, the upper surface of the second lower pattern BP2 and the upper surface of the field insulating layer 105. The interfacial layer 130, the first insulating layer IL1 and the first insertion insulating layer DL1 are formed along the circumferences of the first sheet pattern NS1 and the second sheet pattern NS2.

The first insulating layer IL1 may be formed on the first sheet pattern NS1 along the circumference of the interfacial layer 130. The first insulating layer IL1 may be formed on the second sheet pattern NS2 along the circumference or outer edge of the interfacial layer 130. The first insulating layer IL1 may be extended along the upper surface of the interfacial layer 130 formed on the field insulating layer 105, the first lower pattern BP1 and the second lower pattern BP2. The first insulating layer IL1 may include a high dielectric constant insulating layer.

The first insertion insulating layer DL1 may be formed on the first sheet pattern NS1 along the circumference of the first insulating layer IL1. The first insertion insulating layer DL1 may be formed on the second sheet pattern NS2 along the circumference of the first insulating layer IL1. The first insertion insulating layer DL1 may be extended along the upper surface of the first insulating layer IL1 formed on the field insulating layer 105, the first lower pattern BP and the second lower pattern BP2. The first insertion insulating layer DL1 may include lanthanum oxide.

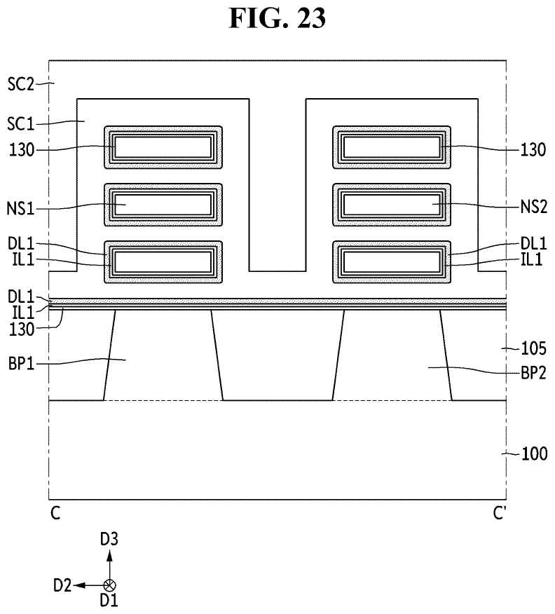

Referring to FIG. 23, a first sacrificial layer SC1 and a second sacrificial layer SC2 are formed on the substrate 100.

The first sacrificial layer SC1 may cover, overlap or be on the plurality of first sheet patterns NS1 and the plurality of second sheet patterns NS2. The second sacrificial layer SC2 may be formed on the first sacrificial layer SC1. The first sacrificial layer SC1 may include TiN but is not limited thereto. The second sacrificial layer SC2 may be a bottom anti-reflective coating (BARC) layer.

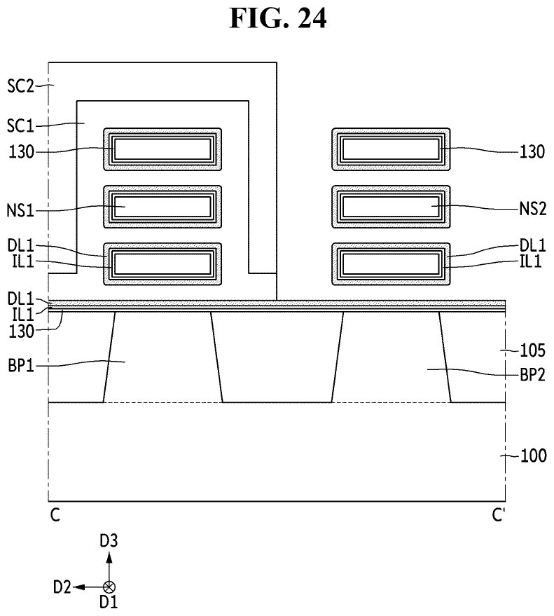

Referring to FIG. 24, the first sacrificial layer SC1 and the second sacrificial layer SC2 formed on the second lower pattern BP2 are removed.

The first sacrificial layer SC1 and the second sacrificial layer SC2, which surround the plurality of second sheet patterns NS2, may be removed. The first sacrificial layer SC1 and the second sacrificial layer SC2, which are formed on the second lower pattern BP2, may be removed to expose the first insertion insulating layer DL1 formed on the plurality of second sheet patterns NS2.

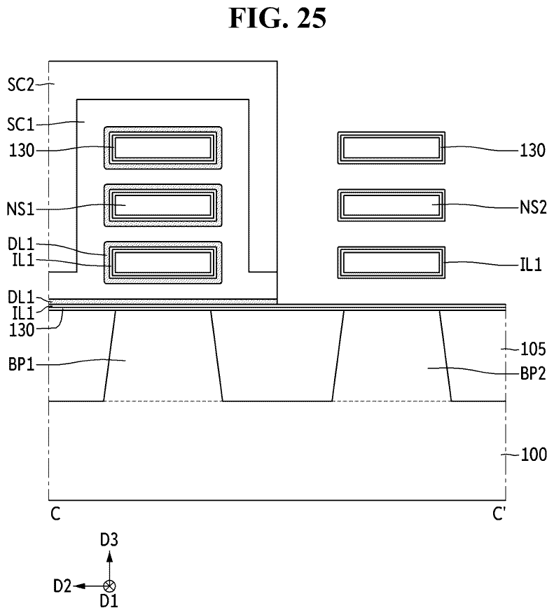

Referring to FIG. 25, the first insertion insulating layer DL1 formed on the plurality of second sheet patterns NS2 along the circumference of the interfacial layer 130 is removed.

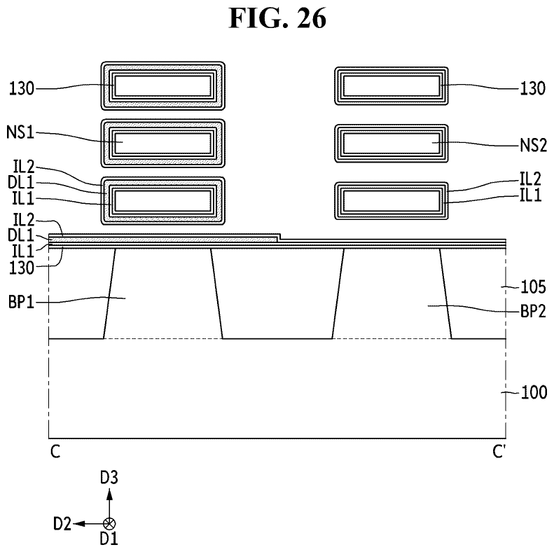

Referring to FIG. 26, the first sacrificial layer SC1 and the second sacrificial layer SC2 formed on the first lower pattern BP1 are removed, and the second insulating layer IL2 is formed.

The first sacrificial layer SC1 and the second sacrificial layer SC2 may be removed to expose the first insertion insulating layer DL1 formed on the plurality of first sheet patterns NS1. Subsequently, the second insulating layer IL2 may be formed on the plurality of first sheet patterns NS1 along the circumference of the first insertion insulating layer DL1. The second insulating layer IL2 may be formed on the plurality of second sheet patterns NS2 along the circumference of the first insulating layer IL1. The second insulating layer IL2 may be extended on the first lower pattern BP1 along the upper surface of the first insertion insulating layer DL1. The second insulating layer IL2 may be extended on the second lower pattern BP2 along the upper surface of the first insulating layer IL1.

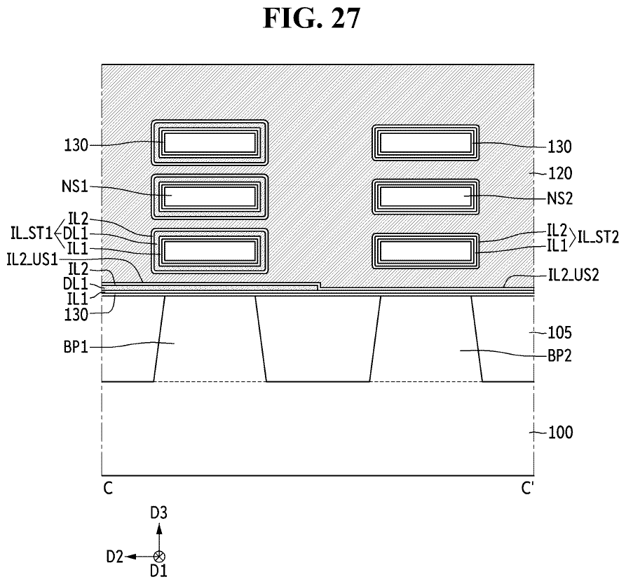

Referring to FIG. 27, the gate electrode 120 is formed on the substrate 100.

The gate electrode 120 may cover, overlap or be on the plurality of first sheet patterns NS1 on the first lower pattern BP1. The gate electrode 120 may cover, overlap or be on the plurality of second sheet patterns NS2 on the second lower pattern BP2. Subsequently, referring to FIG. 4, the second interlayer insulating layer 191 including the gate capping pattern 145 and the upper wiring structure 195 on the gate capping pattern 145 may be formed on the gate electrode 120.

In concluding the detailed description, those skilled in the art will appreciate that many variations and modifications may be made to the described embodiments without substantially departing from the principles of the present inventive concept. Therefore, the disclosed embodiments of the invention are used in a generic and descriptive sense only and not for purposes of limitation.

What is claimed is:

1. A semiconductor device comprising:
a substrate;
a first active pattern on the substrate, comprising a first lower pattern and a plurality of first sheet patterns spaced apart from the first lower pattern in a first direction;
a gate electrode on the substrate, and on the plurality of first sheet patterns;
an interfacial layer between the plurality of first sheet patterns and the gate electrode and along an outer edge of each of the plurality of first sheet patterns; and
a first insulating layer structure between the interfacial layer and the gate electrode and extending along the outer edge of each of the plurality of first sheet patterns,
wherein the first insulating layer structure comprises a first insulating layer along on the interfacial layer, a first insertion insulating layer along on the first insulating layer, and a second insulating layer along on the first insertion insulating layer.

2. The semiconductor device of claim 1, wherein the first insulating layer and the second insulating layer comprise a same material.

3. The semiconductor device of claim 1, wherein the first insertion insulating layer comprises lanthanum oxide.

4. The semiconductor device of claim 1, wherein the first insertion insulating layer comprises aluminum oxide.

5. The semiconductor device of claim 1, further comprising:
a second active pattern on the substrate and spaced apart from the first active pattern in a second direction perpendicular to the first direction, comprising a second lower pattern and a plurality of second sheet patterns spaced apart from the second lower pattern in the first direction, wherein the gate electrode is on the plurality of second sheet patterns; and
a second insulating layer structure between the plurality of second sheet patterns and the gate electrode and extending along an outer edge of each of the plurality of second sheet patterns,
wherein the second insulating layer structure comprises a third insulating layer on the plurality of second sheet patterns and a fourth insulating layer on the third insulating layer.

6. The semiconductor device of claim 5, further comprising a second insertion insulating layer between each of the plurality of second sheet patterns and the gate electrode, between the third insulating layer and the fourth insulating layer, and on the third insulating layer.

7. The semiconductor device of claim 6, wherein the second insertion insulating layer comprises lanthanum oxide.

8. The semiconductor device of claim 7, wherein the first insertion insulating layer comprises lanthanum oxide, and
wherein the second insertion insulating layer comprises aluminum oxide.

9. The semiconductor device of claim 5, wherein the first insulating layer is on the first lower pattern, the first insertion insulating layer is on the first insulating layer, and the second insulating layer is on the first insertion insulating layer,
wherein the third insulating layer is on the second lower pattern, and the fourth insulating layer is on the third insulating layer, and
wherein a distance from the substrate in the first direction to an upper surface of the second insulating layer that overlaps the first lower pattern in the first direction is greater than a distance from the substrate in the first direction to an upper surface of the fourth insulating layer that overlaps the second lower pattern in the first direction.

10. The semiconductor device of claim 5, further comprising:
a first source/drain pattern on the first insulating layer structure and the plurality of first sheet patterns in a third direction; and
a second source/drain pattern on the second insulating layer structure and the plurality of second sheet patterns in the third direction,
wherein the first source/drain pattern and the second source/drain pattern are in contact with the first insulating layer structure and the second insulating layer structure respectively.

11. The semiconductor device of claim 1, further comprising a first source/drain pattern on the substrate, on the first insulating layer structure, and on the plurality of first sheet patterns,
wherein the first source/drain pattern is in contact with the first insulating layer structure.

12. The semiconductor device of claim 1, wherein the first insulating layer structure further comprises a third insertion insulating layer on the second insulating layer, and
wherein the third insertion insulating layer comprises lanthanum oxide.

13. A semiconductor device comprising:
a substrate;
a first active pattern on the substrate, comprising a first lower pattern and a plurality of first sheet patterns spaced apart from the first lower pattern in a first direction;
a second active pattern on the substrate and spaced apart from the first active pattern in a second direction perpendicular to the first direction, and comprising a second lower pattern and a plurality of second sheet patterns spaced apart from the second lower pattern in the first direction;
a gate electrode on the substrate, and on the plurality of first sheet patterns and the plurality of second sheet patterns;
a first insulating layer structure between each of the plurality of first sheet patterns and the gate electrode and along an outer edge of each of the plurality of first sheet patterns; and
a second insulating layer structure between each of the plurality of second sheet patterns and the gate electrode and along an outer edge of each of the plurality of second sheet patterns,
wherein the first insulating layer structure comprises a first insulating layer on each of the plurality of first sheet patterns, and a second insulating layer on the first insulating layer,
wherein the second insulating layer structure comprises a third insulating layer on each of the plurality of second sheet patterns, and a fourth insulating layer on the third insulating layer, and
wherein the first insulating layer structure comprises a first insertion insulating layer between each pair of first and second insulating layers, but the second insulating layer structure does not comprise the first insertion insulating layer.

14. The semiconductor device of claim 13, wherein the first insertion insulating layer comprises lanthanide oxide.

15. The semiconductor device of claim 13, wherein the first, second, third, and fourth insulating layers comprise a same material.

16. The semiconductor device of claim 13, wherein the first insulating layer is on the first lower pattern, the first insertion insulating layer is on the first insulating layer, the second insulating layer is on the first insertion insulating layer, and the gate electrode is on the second insulating layer, and
the third insulating layer is on the second lower pattern, the fourth insulating layer is on the third insulating layer, and the gate electrode is on the fourth insulating layer.

17. The semiconductor device of claim 16, wherein a distance from the substrate to an upper surface of the second insulating layer that overlaps the first lower pattern in the first direction is greater than a distance from the substrate to an upper surface of the fourth insulating layer that overlaps the second lower pattern in the first direction.

18. The semiconductor device of claim 13, wherein the first insulating layer structure further comprises a third insertion insulating layer on the second insulating layer, and
wherein the third insertion insulating layer comprises lanthanum oxide.

19. A semiconductor device comprising:
a substrate;
a first active pattern on the substrate, comprising a first lower pattern and a plurality of first sheet patterns spaced apart from the first lower pattern in a first direction;
a second active pattern on the substrate and spaced apart from the first active pattern in a second direction perpendicular to the first direction, and comprising a second lower pattern and a plurality of second sheet patterns spaced apart from the second lower pattern in the first direction;
a gate electrode on the substrate, on the plurality of first sheet patterns and the plurality of second sheet patterns;
an interfacial layer between each of the plurality of first sheet patterns and the gate electrode along an outer edge of each of the plurality of first sheet patterns, and between each of the plurality of second sheet patterns and the gate electrode along an outer edge of each of the plurality of second sheet patterns, ;
a first insulating layer structure between the interfacial layer and the gate electrode and on each of the plurality of first sheet patterns; and
a second insulating layer structure between the interfacial layer and the gate electrode and on each of the plurality of second sheet patterns,
wherein the first insulating layer structure comprises a first insulating layer on the interfacial layer, a first insertion insulating layer on the first insulating layer, and a second insulating layer on the first insertion insulating layer,
wherein the second insulating layer structure comprises a third insulating layer on the interfacial layer and a fourth insulating layer on the first insulating layer,
wherein the first insertion insulating layer comprises lanthanum oxide, and
wherein the first, second, third, and fourth insulating layers comprise a same material.

20. The semiconductor device of claim 19, wherein the second insulating layer structure further comprises a second insertion insulating layer between the third insulating layer and the fourth insulating layer, and
wherein the first insertion insulating layer comprises lanthanum oxide and the second insertion insulating layer comprises aluminum oxide.
